(19) United States
(12) Patent Application Publication
(10) Pub. No.: US 2021/0274682 A1
(43) Pub. Date: Sep. 2, 2021

(54) HEAT SINK DEVICE PROVIDED WITH A SECONDARY COLD PLATE

(71) Applicants: Continental Automotive France, Toulouse (FR); Continental Automotive GmbH, Hannover (DE)

(72) Inventor: Philippe Lopez, Toulouse (FR)

(21) Appl. No.: 17/258,278

(22) PCT Filed: Jul. 16, 2019
(86) PCT No.: PCT/EP2019/069094

§ 371 Date: Jan. 6, 2021

(30) Foreign Application Priority Data
Jul. 16, 2018 (FR) 1856533

(51) Int. Cl. H05K 7/20; H05K 1/02

(52) U.S. Cl. CPC H05K 7/20509; H05K 2201/066; H05K 1/0206; H05K 7/205

(57) ABSTRACT

A heat sink device including a body and at least one main cold plate in contact with the at least one casing of an electronic device, the electronic device furthermore being provided with at least two pins for connecting to a printed circuit board and generating heat when it is activated. At least one secondary cold plate is in contact with the printed circuit board in the vicinity of the connecting pins.

The technical field of the invention is that of electronic devices and more particularly the thermal dissipation of the heat generated by such devices.

Electronic devices, such as transistors or converters, are subjected to significant Joule heating, creating a release of heat. An electronic device is generally disposed in a casing in order to protect it from its surroundings and is connected to a printed circuit board 1 via connecting pins 2b. The heat thus generated by Joule heating in the device builds up rapidly in the casing 2a and has to be evacuated so as not to build up in the device to such an extent that it prevents the operation thereof or even destroys it by melting or combustion.

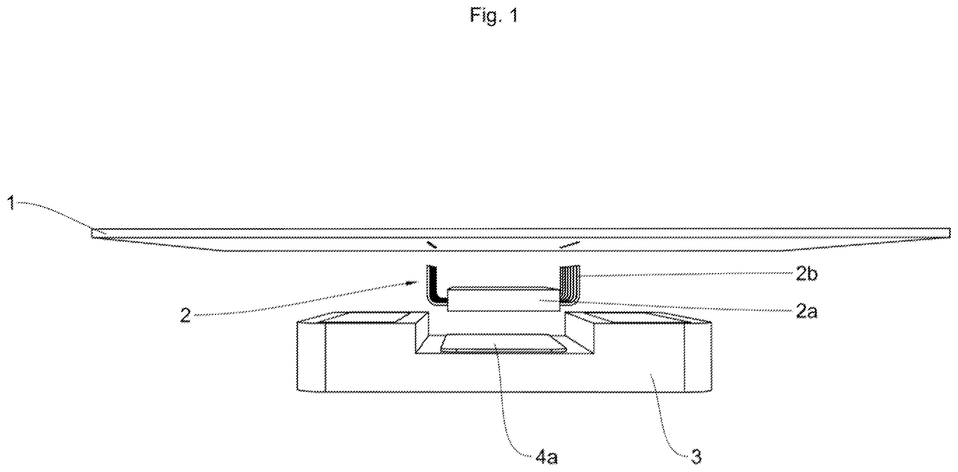

In order to avoid this, it is common practice to use heat sink devices as illustrated in FIG. 1, which generally comprise a cold plate 4a in contact with a casing 2a.

Depending on the embodiment chosen, the cold plate 4a is thermally connected to the body 3 of the heat sink device such as a mass with a high thermal capacity so as to form a heat sink and/or a large heat-exchange surface so as to form a heat sink, either by direct contact or via a heat pipe for transporting the heat generated.

Despite precision machining, the functional clearance inherent to the thermal performance is not optimum on account of the presence of the electronic device producing the Joule heating, which has, through its construction, significant tolerances, thereby reducing the effective thermal conductivity of the heat sink device.

In order to improve this contact, a thermal paste having high thermal conductivity is employed in order to ensure the interface between the cold plate 4a and the casing 2a of the electronic device. In a preferred embodiment, this thermal paste is electrically insulating so as to avoid any short circuit.

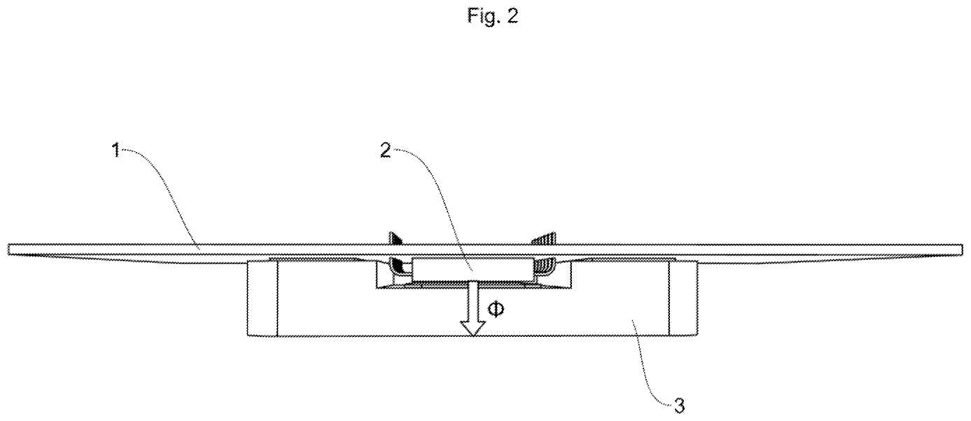

The heat sink device thus makes it possible to dissipate the heat generated by the electronic device at the casing 2a, as illustrated in FIG. 2. The arrow Φ illustrates the heat flow.

The performance of such heat sink devices is thus limited by the thermal conductivity of each element involved, the thermal conductivity generally being linked to the materials employed.

Following a significant research period during the development of microelectronics, it has become apparent that the materials currently used cannot be improved in order to make it possible to increase the effective thermal conductivity of heat sink devices.

Other research topics involve replacing the ambient air with gases with high thermal conductivity in order to improve the effective thermal conductivity of the dissipation means, or using significant coolants in order to transport the heat toward more massive heat sinks. These solutions are not, however, applicable to the electronic devices commonly used in motor vehicles.

Nevertheless, there remains a need for heat sink devices that exhibit improved dissipation compared with the current state of the art for a similar volume or mass of material and that function in ambient air.

The subject of the invention is a heat sink device comprising a body and at least one main cold plate in contact with the at least one casing of an electronic device, the electronic device furthermore being provided with at least two pins for connecting to a printed circuit board and generating heat when it is activated, characterized by the fact that it comprises at least one secondary cold plate in contact with the printed circuit board in the vicinity of the connecting pins.

The device may comprise at least one via formed in the printed circuit board next to the at least one connecting pin, each via comprising a material of which the thermal conductivity is greater than the thermal conductivity of the printed circuit board.

The secondary cold plate may be in direct or indirect contact with at least one via.

A via may be filled with a composite material based on graphite or metal.

Vias may be formed in a dissipation zone adjacent to a connection zone in which a plurality of connecting pins of the electronic device are connected to the printed circuit board, the first dissipation zone being separate from the facing zone of the casing of the electronic device.

The vias of a dissipation zone may form a periodic array.

Further aims, features and advantages of the invention will become apparent from reading the following description, given solely by way of nonlimiting example, and with reference to the appended drawings, in which:

FIG. 1 illustrates the main elements of a heat sink device according to the prior art,

FIG. 2 illustrates the heat flows in a heat sink device according to the prior art,

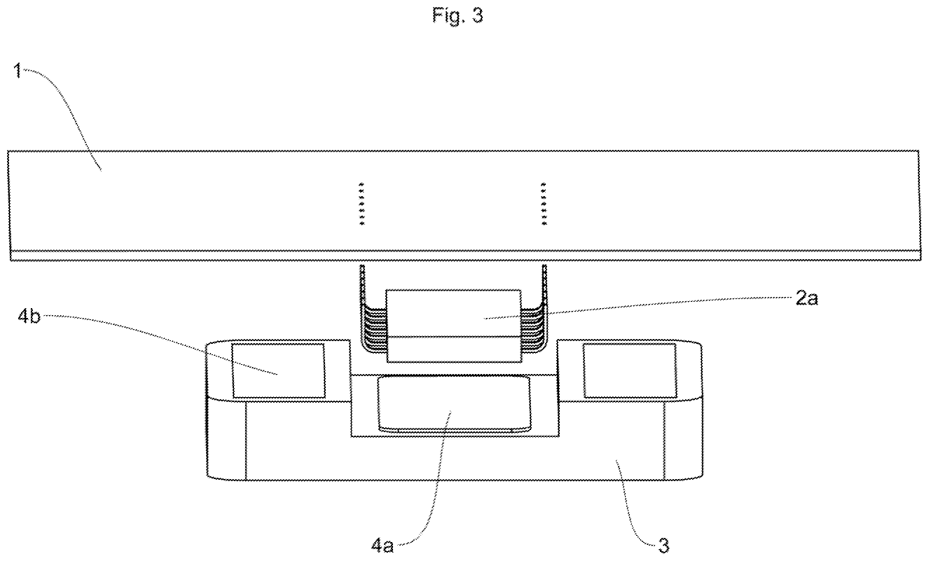

FIG. 3 illustrates the main elements of a first embodiment of a heat sink device provided with a secondary cold plate according to the invention,

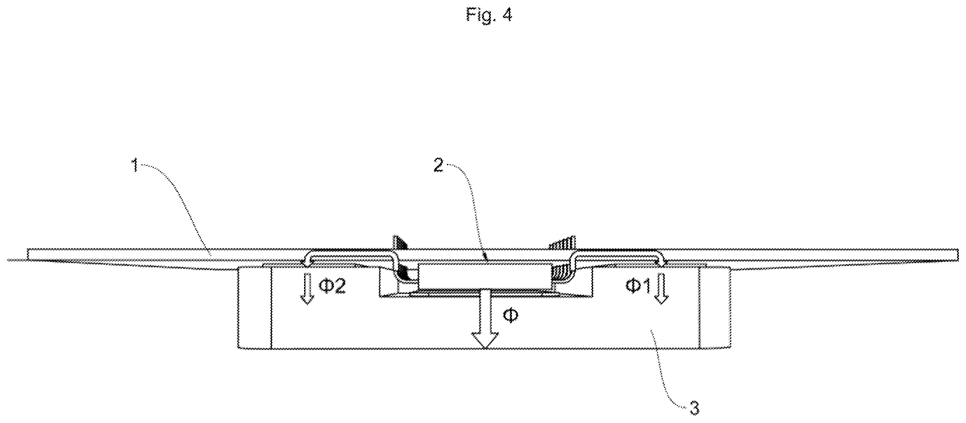

FIG. 4 illustrates the heat flows in a heat sink device provided with a secondary cold plate according to a first embodiment, and

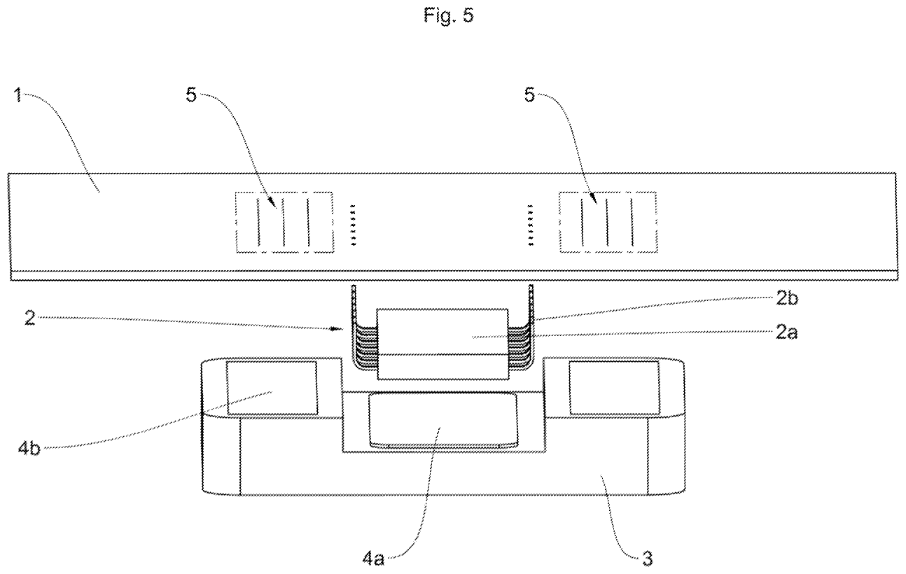

FIG. 5 illustrates the main elements of a second embodiment of a heat sink device provided with a secondary cold plate according to the invention.

In an electronic device, the heat generated in the components is transmitted to the casing 2a and to the connecting pins 2b.

As set out in the introduction, the current heat sink devices make it possible evacuate the heat from the casing 2a. However, the part of the heat that diffuses through the connecting pins 2b is not picked up. This heat diffuses into the printed circuit board, where it has detrimental effects.

In order to overcome this and to improve the effective thermal conductivity of the heat sink device, the invention provides for the heat sink device employed in order to cool the casing 2a of the electronic device to be modified in order to provide at least one secondary cold plate 4b disposed in direct or indirect contact with the printed circuit board in the vicinity of the connection zone of the connecting pins to the printed circuit board, and in thermal contact by way of a thermal paste. FIG. 3 shows an exploded view of such an arrangement.

A heat sink device modified in this way has improved effective thermal conductivity compared with the prior art since the heat flows passing through the connecting pins of the electronic device are taken into account. FIG. 4 illustrates a side view of the arrangement, and shows the main heat flows by way of the arrows numbered Φ,Φ1,Φ2.

In a second embodiment that is illustrated in FIG. 5, the invention also provides at least one via 5 formed in the printed circuit board 1 in the vicinity of the connecting pins 2b so as to form heat trap zones. In a preferred embodiment, these vias are filled with a material with high thermal conductivity, such as graphite or a metal.

The heat circulating in the connecting pins 2b diffuses into the printed circuit board 1 at the connection points of the connecting pins 2b to the electrical tracks of the printed circuit board. Once in the printed circuit board and in the electrical tracks, this heat diffuses in accordance with the laws of thermal diffusion toward the zones of greater thermal conductivity. The vias 5 formed in the printed circuit board 1 within the scope of the invention exhibit greater thermal conductivity than the other elements of the printed circuit board 1, and so the heat dissipated is drawn thereto.

In order to avoid the creation of new hot points, the heat sink device employed to cool the casing of the electronic device and the printed circuit board described in the first embodiment is modified such that at least one secondary cold plate 4b is disposed facing each via 5 or group of vias 5 and in thermal contact by way of a thermal paste.

A heat sink device modified in this way combined with a printed circuit board 1 provided with at least one via 5 forming a heat trap exhibits improved effective thermal conductivity on account of the capturing by the vias 5 of the heat diffusing through the connecting pins 2b and then the transfer of heat thus captured toward the secondary cold plates 4b.

The heat flows corresponding to the heat flows Φ1 and Φ2 illustrated in FIG. 4 for the first embodiment are then improved compared therewith.

1. A heat sink device comprising:
a body,
at least one main cold plate in contact with the at least one casing of an electronic device, the electronic device furthermore being provided with at least two pins for connecting to a printed circuit board and generating heat when it is activated, and
at least one secondary cold plate in contact with the printed circuit board in the vicinity of the connecting pins.

2. An assembly comprising a heat sink device as claimed in claim 1 and the printed circuit board, in which at least one via is formed next to the at least one connecting pin, each via comprising a material of which the thermal conductivity is greater than the thermal conductivity of the printed circuit board.

3. The assembly as claimed in claim 2, wherein the secondary cold plate is in direct or indirect contact with at least one via.

4. The assembly as claimed in claim 2, wherein a via is filled with a composite material based on graphite or metal.

5. The assembly as claimed in claim 2, wherein vias are formed in a dissipation zone adjacent to a connection zone in which a plurality of connecting pins of the electronic device are connected to the printed circuit board, the first dissipation zone being separate from the zone facing the casing of the electronic device.

6. The assembly as claimed in claim 5, wherein the vias of a dissipation zone form a periodic array.

7. The assembly as claimed in claim 3, wherein a via is filled with a composite material based on graphite or metal.
